(19) United States
(12) Patent Application Publication
(10) Pub. No.: US 2012/0061825 A1
(43) Pub. Date: Mar. 15, 2012

(54) CHIP SCALE PACKAGE AND METHOD OF FABRICATING THE SAME

(75) Inventors: Chiang-Cheng Chang, Tiachung (TW); Chien-Ping Huang, Taichung (TW); Chun-Chi Ke, Taichung (TW)

(73) Assignee: SILICONWARE PRECISION INDUSTRIES CO., LTD., Taichung (TW)

(21) Appl. No.: 12/906,501

(22) Filed: Oct. 18, 2010

(30) Foreign Application Priority Data
Sep. 9, 2010 (TW) 099130441

(51) Int. Cl. H01L 23/498; H01L 21/50

(52) U.S. Cl. 257/737; 438/118; 257/E23.068; 257/E21.499

(57) ABSTRACT

A chip scale package and a method of fabricating the chip scale package. The chip scale package includes a encapsulant having a first surface and a second surface opposing the first surface; a conductive pillar formed in the encapsulant and exposed from the first surface and the second surface; a chip embedded in the encapsulant while exposed from the first surface; a dielectric layer formed on the first surface, the conductive pillar and the chip; a circuit layer formed on the dielectric layer; a plurality of conductive blind vias formed in the dielectric layer electrically connecting the circuit layer, electrode pads and the conductive pillar; and a solder mask layer formed on the dielectric layer and the circuit layer, thereby using conductive pillars to externally connect with other electronic devices as required to form a stacked structure.

### BACKGROUND OF THE INVENTION

1. Field of the Invention

This invention relates to packages and methods of fabricating the same, and more particularly, to a chip scale package and a method of fabricating the same.

2. Description of Related Art

With the advancement of semiconductor technology, a semiconductor product may be in various package forms. In order to pursue the goal of compact size, a chip scale package (CSP) is brought to the market that is characterized in that the chip scale package is the same as or slightly greater than a chip in size.

U.S. Pat. Nos. 5,892,179, 6,103,552, 6,287,893, 6,350,668 and 6,433,427 disclosed a conventional CSP structure, in which a built-up structure is formed on a chip directly, without using a chip carrier, such as a substrate or a lead frame. A redistribution layer (RDL) technique is used to redistribute electrode pads on the chip to desired locations.

However, the above CSP structure has an disadvantage that the application of the RDL technique and the conductive traces applied on the chip are limited by the size of the chip or the area of an active surface of the chip. In consequence, as the chip is more integral and smaller in size, there is no sufficient area of the chip where a great number of solder balls may be installed that may be electrically connected to other electronic devices.

To address the disadvantage, U.S. Pat. No. 6,271,469 disclosed a method of fabricating a wafer-level chip scale package (WLCSP), including forming a built-up package on a chip, so as to provide a spacious enough surface area on which a great number of input/output ends or solder balls may be installed.

As shown in FIG. 1A, a glue film 11 is prepared, and a plurality of chips 12 are adhered to the glue film 11 with an active surface 121 of each of the chips 12 facing the glue film 11. The glue film 11 is, for example, a thermally sensitive glue film. As shown in FIG. 1B, a package molding process is performed, in which an encapsulant 13 such as epoxy resin encapsulates an inactive surface 122 and lateral surfaces of the chip 12, and the glue film 11 is thermally removed, such that the active surface 121 of the chip 12 is exposed. As shown in FIG. 1C, the RDL technique is employed, to apply a dielectric layer 14 on the active surface 121 of the chip 12 and the encapsulant 13, form a plurality of openings that penetrate the dielectric layer 14 to expose the electrode pads 120 on the chip 12, form a circuit layer 15 on the dielectric layer 14, electrically connect the circuit layer 15 to the electrode pads 120, apply a solder mask layer 16 on the circuit layer 15, implant solder balls 17 on predetermined positions of the circuit layer 15, and perform a singulation process.

Through the above processes, more solder balls 17 may be formed to be connected with other electronic devices, because the encapsulant 13 that encapsulates the chip 12 may provide a surface area greater than the active surface 121 of the chip 12.

However, the drawbacks of the above processes include that since the chip 12 is adhered to the glue film 11 with the active surface 121 facing the glue film 11, the glue film 11 is likely extended or contracted due to the heating to the glue film 11, and, as such, the chip 12 is offset, and that the softened glue film 11 due to the heat during the package mold process makes the chip 12 to offset, and the circuit layer 15 cannot be connected to the electrode pads 120 of the chip 12 during the subsequent RDL process, which results in poor electrical connection quality.

Please refer to FIG. 2. In another package mold, because the glue film 11′, when heated, is easily softened, an excessive glue 130 is likely formed on the active surface 121 of the chip 12, or even contaminates the electrode pads 120. As a result, the circuit layer is in poor contact with the electrode pads of the chip 12 during the subsequent RDL process, and thus the yield is decreased.

Please refer to FIG. 3A. During the above package molding process, only the glue film 11 is used to support the plurality of chips 12. Therefore, the glue film 11 and the encapsulant 13 suffer server warpage 110 problems, especially when the encapsulant 13 is very thin. Accordingly, the dielectric layer 14 that is applied on the chip 12 during the subsequent RDL process may have uneven thickness. A hard carrier 18 is thus required additionally, as shown in FIG. 3B, and the encapsulant 13 may be fixed to the hard carrier 18 with a glue 19 and be flattened. After the RDL process is complete and the carrier 18 is removed, a glue 190 is likely residual on the encapsulant 13, as shown in FIG. 3C. Other related techniques are disclosed in U.S. Pat. Nos. 6,498,387, 6,586,822, 7,019,406 and 7,238,602.

As shown in FIG, 3D, a stacking process cannot be performed unless the encapsulant 13 has been drilled, a through mold via (TMV) process has been performed to the encapsulant 13 to form a plurality of vias, the vias have been filled with a conductive material 100 by electroplating or electroless plating processes to form a plurality of conductive vias 10, and solder balls 17′ have been formed on the conductive vias 10 for an electronic device 1 of another package to be mounted thereon. However, penetrating the encapsulant 13 is complicated, and the conductive material 100 needs to be filled in the vias when forming the conductive vias 10, which increases the fabrication time and cost.

Therefore, how to provide a chip scale package and a method of fabricating the same, to overcome the drawbacks of the prior art, ensure the electrical connection quality between the circuit layer and the electrode pads, improve the reliability of the product, and reduce the fabrication cost, is becoming one of the most important issues in the art.

### SUMMARY OF THE INVENTION

The present invention provides a chip scale package, which comprises: an encapsulant having a first surface and a second surface opposing the first surface; conductive pillars formed in the encapsulant and exposed from the first surface and the second surface of the encapsulant; a chip embedded in the encapsulant and having an active surface exposed from the first surface of the encapsulant and an inactive surface opposing the active surface, a plurality of electrode pads formed on the active surface; a dielectric layer formed on the first surface of the encapsulant, the conductive pillars, and the active surface of the chip; a circuit layer formed on the dielectric layer; conductive blind vias formed in the dielectric layer and electrically connecting the circuit layer to the electrode pads and the conductive pillars; and a solder mask layer formed on the dielectric layer and the circuit layer and having a plurality of first holes that expose a part of the circuit layer.

In an embodiment of the present invention, the conductive pillars are made of copper.

In an embodiment of the present invention, a metal layer is formed on the conductive pillars, allowing the metal layer to be exposed from the second surface of the encapsulant, and allowing a conductive element to be formed on the exposed metal layer.

In an embodiment of the present invention, the inactive surface of the chip is exposed from the second surface of the encapsulant.

In an embodiment of the present invention, the conductive pillars and the second surface of the encapsulant are at the same height, or the second surface of the encapsulant has a plurality of second holes that expose the conductive pillars, allowing the conductive element to be formed on the exposed conductive pillars.

In an embodiment of the present invention, the package further comprises a conductive element that is mounted on the circuit layer in the first holes.

In an embodiment of the present invention, the package further comprises a built-up structure that is formed on the dielectric layer and the circuit layer, and the solder mask layer is formed on an outermost layer of the built-up structure.

The present invention further provides a method of fabricating a chip scale package, comprising: forming a plurality of neighboring conductive pillars on a carrier, and defining a chip-mounted region on the carrier; disposing within the chip-mounted region a chip having an active surface and an inactive surface opposing the active surface, with the active surface facing the carrier, wherein a plurality of the electrode pads are formed on the active surface; forming on the carrier, the conductive pillars and the chip an encapsulant to encapsulate the chip, the encapsulant having a first surface attached to the carrier and an exposed second surface; removing the carrier to expose the first surface of the encapsulant, the conductive pillars and the active surface of the chip; forming a dielectric layer on the first surface of the encapsulant, the conductive pillars, and the active surface of the chip; forming a circuit layer on the dielectric layer, and forming conductive blind vias in the dielectric layer, allowing the circuit layer to be electrically connected via the conductive blind vias to the electrode pads and the conductive pillars; forming on the dielectric layer and the circuit layer a solder mask layer that has a plurality of first holes that expose a part of the circuit layer; and exposing the conductive pillars from the second surface of the encapsulant.

In an embodiment of the present invention, the carrier is made of copper.

In an embodiment of the present invention, the carrier is fabricated by: providing a substrate; forming on the substrate a resistive layer that has a plurality of openings that expose a part of the substrate; removing the part of the substrate in the openings, allowing the conductive pillars to be formed under the resistive layer; and removing the resistive layer, allowing the remaining substrate to act as the carrier.

In an embodiment of the present invention, a metal layer is formed on the conductive pillars, allowing the metal layer to be exposed from the second surface of the encapsulant, and allowing the conductive element to be formed on the exposed metal layer.

In an embodiment of the present invention, the carrier is fabricated by: providing a substrate; forming on the substrate a resistive layer that has a plurality of openings that expose a part of the substrate; forming the metal layer on the substrate in the openings; and removing the resistive layer and the part of the substrate under the resistive layer, allowing the conductive pillars to be formed under the metal layer, and the remaining substrate to act as the carrier.

In an embodiment of the present invention, the carrier is etched and removed.

In an embodiment of the present invention, the method further comprises applying an adhesive layer on the active surface of the chip, allowing the chip to be positioned within the chip-mounted region of the carrier, and removing the adhesive layer after the carrier is removed.

In an embodiment of the present invention, the inactive surface of the chip is exposed from the encapsulant.

In an embodiment of the present invention, the method further comprises removing the encapsulant on the conductive pillars, allowing the conductive pillars to be at the same height as the second surface of the encapsulant, or comprises forming a plurality of second holes on the second surface of the encapsulant to expose the conductive pillars.

In an embodiment of the present invention, the method further comprises forming a conductive element on the exposed conductive pillars.

In an embodiment of the present invention, the second holes are formed by a laser drilling technique.

In an embodiment of the present invention, the method further comprises forming a conductive element on the circuit layer in the first holes.

In an embodiment of the present invention, the method further comprises forming on the dielectric layer and the circuit layer a built-up structure, and the solder mask layer is formed on an outermost layer of the built-up structure.

In sum, in the chip scale package and the method of fabricating the same of the present invention the chip is mounted on the carrier that is formed with conductive pillars , the encapsulant covers the chip and the conductive pillars, and then the carrier is removed, for the RDL process to be performed subsequently, so as to prevent the chip from being adhered directly to the glue film that is easily to be softened when heated, prevent the encapsulant to generate excessive glue and contaminate and offset the chip, ensure that the circuit layer is in well contact with the electrode pads during the subsequent fabrication processes, and increase the yield.

Moreover, the conductive pillars may increase the supporting force, and the problems of the prior art that the warpage happens because only the glue film is used to provide the supporting force and glue is residual on the encapsulant are solved.

Further, through the design of the conductive pillars, other electronic devices may be connected externally when the stacking process is performed, without penetrating the encapsulant to form the conductive vias, as the prior art teaches. Therefore, the fabrication process of the present invention is simplified, and the fabrication time and cost are reduced because no need of filling with the conductive material.

### BRIEF DESCRIPTION OF DRAWINGS

The invention can be more fully understood by reading the following detailed description of the preferred embodiments, with reference made to the accompanying drawings, wherein:

FIGS. 1A-1C illustrate a method of fabricating a wafer-level chip scale package disclosed in U.S. Pat. No. 6,271,469;

FIG. 2 illustrates a wafer-level chip scale package disclosed in U.S. Pat. No. 6,271,469 that suffers an excessive glue problem;

FIGS. 3A-3D illustrate a wafer-level chip scale package disclosed in U.S. Pat. No. 6,271,469 that suffers the problems of encapsulant warpage, additionally installed carrier, residual glue on the encapsulant surface, and difficult to stack;

FIGS. 4A-4H illustrate a chip scale package and a method of fabricating the chip scale package according to the present invention, wherein FIG. 4A′ is another embodiment of FIG. 4A, FIG. 4F′ illustrates a method of fabricating a built-up structure, FIGS. 4G′ and 4G″ illustrate two different embodiments of the FIG. 4G, and FIGS. 4H′ and 4H″ illustrate two different embodiments of the FIG. 4H; and

FIGS. 5A-5C illustrate a method of fabricating a conductive pillar of a chip scale package according to the present invention, wherein FIGS. 5A′-5C′ are another embodiment of FIGS. 5A-5C.

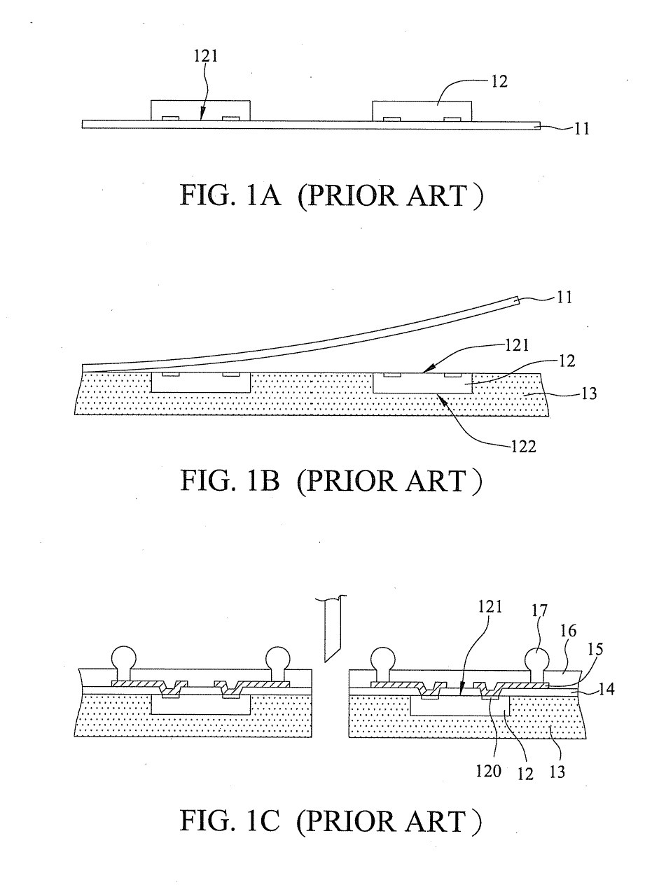

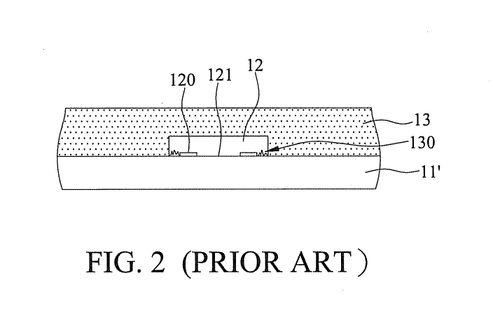

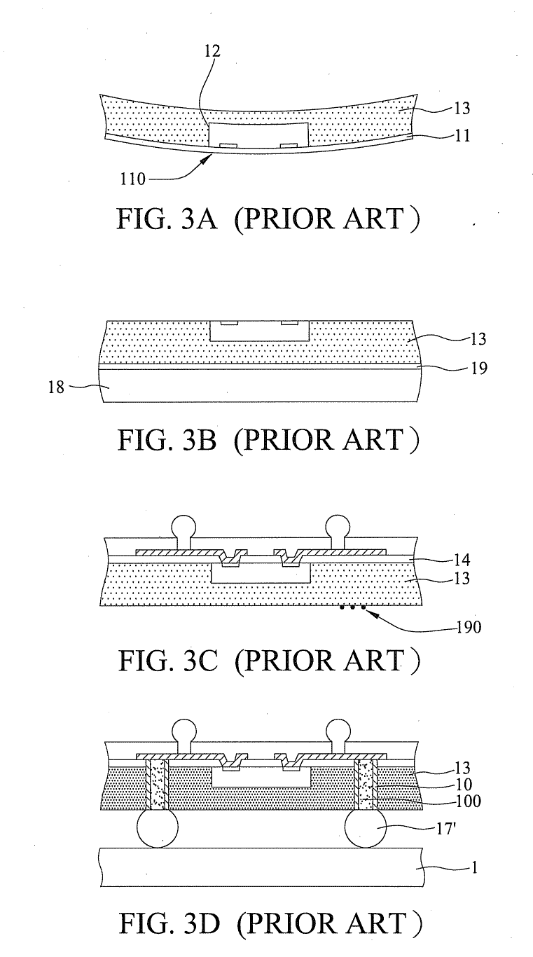

### DETAILED DESCRIPTION OF PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

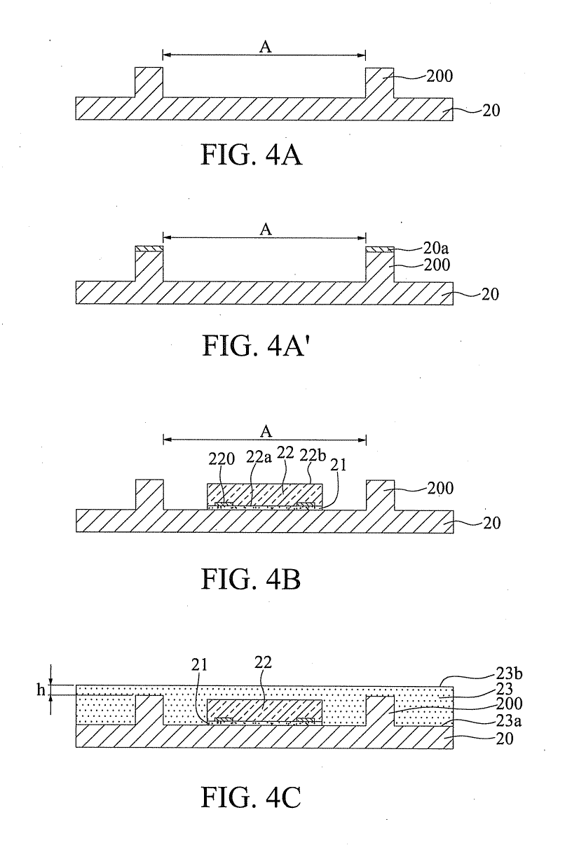

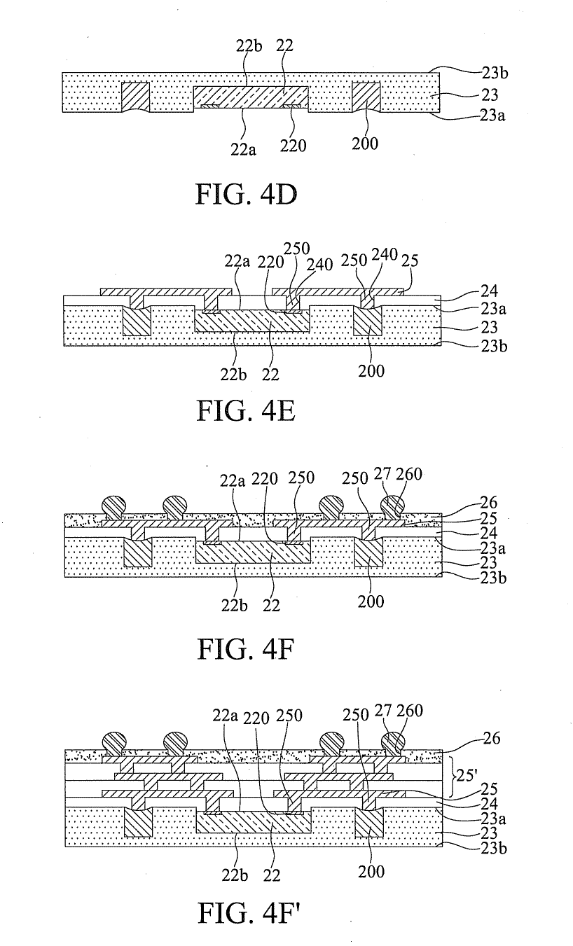

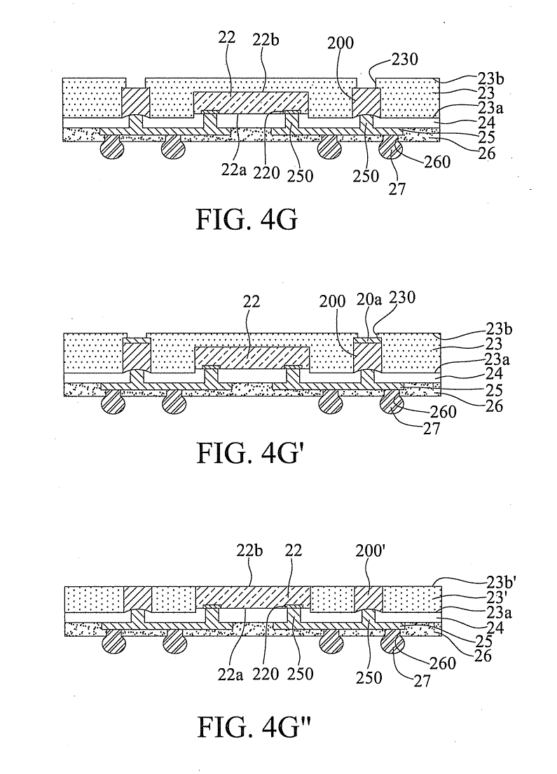

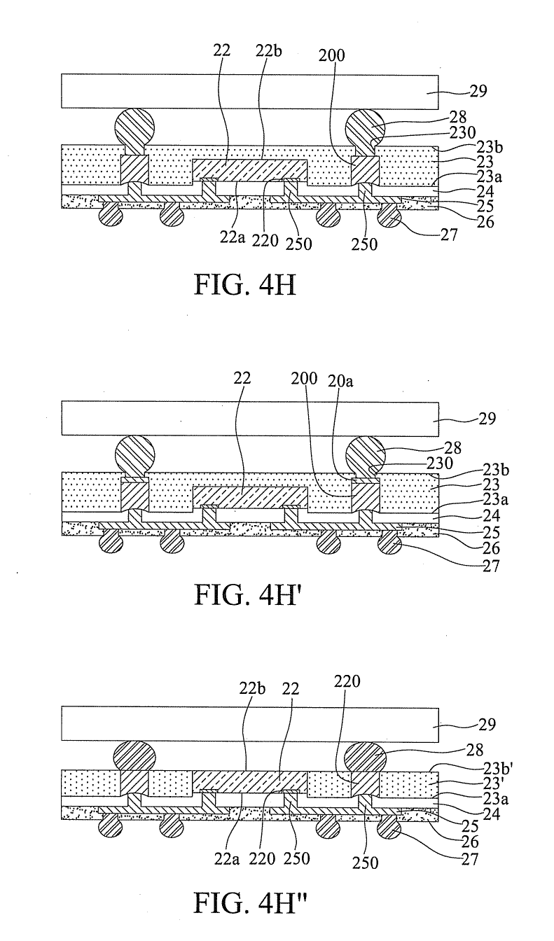

Please refer to FIGS. 4A to 4H, which illustrate a method of fabricating a chip scale package.

As shown in FIG. 4A, a carrier 20 is provided, and a plurality of conductive pillars 200 and a chip-mounted region A are formed on the carrier 20. The carrier 20 is made of copper.

As shown in FIG. 4A′, a metal layer 20a may be also formed on a top surface of the conductive pillars 200. The metal layer 20a may comprise nickel, palladium or gold or be in a stacked structure.

As shown in FIG. 4B, a chip 22 is mounted on the chip-mounted region A of the carrier 20. The chip 22 has an active surface 22a and an inactive surface 22b opposing the active surface 22a. A plurality of electrode pads 220 are disposed on the active surface 22a. The chip 22 is mounted on the carrier 20 with the active surface 22a facing the carrier 20. In the embodiment, an adhesive layer 21 is coated on the active surface 22a, such that the chip 22 may be fixed to the carrier 20.

As shown in FIG. 4C, an encapsulant 23 is formed on the carrier 20, the conductive pillars 200 and the chip 22, to encapsulate the chip 22. The encapsulant 23 has a first surface 23a that is combined with the carrier 20, and an exposed second surface 23b. In the embodiment, the encapsulant 23 encapsulates the inactive surface 22b of the chip 22, and the conductive pillars 200 are spaced from the second surface 23b of the encapsulant 23 at a distance h of 10 to 50 μm, but not limited thereto.

As shown in FIG. 4D, the carrier 20 is etched and removed, such that the first surface 23a of the encapsulant 23 and the conductive pillars 200 are exposed. Then, the adhesive layer 21 is removed by a chemical agent, so as to expose the active surface 22a of the chip 22.

In the embodiment, when the carrier 20 is removed, no metal material or glue will be residual on the first surface 23a of the encapsulant 23.

As shown in FIG. 4E, a redistribution layer (RDL) process is performed. First, a dielectric layer 24 is formed on the first surface 23a of the encapsulant 23, the conductive pillars 200, and the active surface 22a of the chip 22. Then, a plurality of blind vias 240 are formed in the dielectric layer 24, so as to expose the conductive pillars 200 and the electrode pads 220. A patterned step is then performed, so as to form conductive blind vias 250 in the blind vias 240, and form a circuit layer 25 on the conductive blind vias 250 and on the dielectric layer 24, allowing the circuit layer 25 to be electrically connected via the conductive blind vias 250 to the electrode pads 220 and the conductive pillar 200.

As shown in FIG. 4F, a solder mask layer 26 is formed on the dielectric layer 24 and the circuit layer 25. The solder mask layer 26 has a plurality of first holes 260, such that a part of the circuit layer 25 is exposed from the first holes 260. Therefore, in the subsequent process a conductive element 27 such as solder balls may be formed on the circuit layer 25 in the first holes 260, in order to connect other electronic devices, such as a circuit board and a semiconductor chip, externally.

As shown in FIG. 4F′, a built-up structure 25′ may be alternatively formed on the dielectric layer 24 and the circuit layer 25 first, and then the solder mask layer 26 is formed on an outermost layer of the built-up structure 25′, allowing a part of the outermost layer circuit to be exposed from the first holes 260, and form the conductive element 27 on the circuit in the first holes 260. The built-up structure 25′ has at least one dielectric layer, a circuit formed on the dielectric layer, and conductive blind vias formed in the dielectric layer and electrically connected to the circuit layer 25 and the circuit.

As shown in FIG. 4G, a laser-drilling technique is employed to form a plurality of second holes 230 on the second surface 23b of the encapsulant 23, allowing the conductive pillars 200 to be exposed from the second surface 23b of the encapsulant 23. In another embodiment, another built-up structure may be further formed on the second surface 23b of the encapsulant 23 (not shown).

As shown in FIG. 4H, a conductive element 28 such as solder balls is formed on the conductive pillars 200 in the second holes 230, allowing another electronic device, such as a circuit board or another package, to be externally connected thereto.

Through the design of the conductive pillars 200, when a stack process is performed solder balls may be used to connect another electronic device 29 directly, without the need to penetrating the encapsulant to form the conductive vias. Therefore, the present invention has a simplified process, does not need the conductive material, and has a reduced fabrication time and cost.

In another embodiment, as shown in FIGS. 4G′ and 4H′, if the above-described processes are performed according to the structure shown in FIG. 4A′, the metal layer 20a is exposed from the second surface 23b of the encapsulant 23, such that the conductive element 28 is formed on the metal layer 20a in the second holes 230, allowing the electronic device 29 to be connected thereto externally.

In another embodiment, as shown in FIGS. 4G″ and 4H″, the encapsulant 23 on the conductive pillars 200′ and the inactive surface 22b of the chip 22 are removed, allowing the residual encapsulant 23′ to form a new second surface 23b′, allowing the conductive pillars 200′ and the inactive surface 22b of the chip 22 to be exposed from the new second surface 23b′ of the encapsulant 23′, allowing the inactive surface 22b of the chip 22 to dissipate heat, and allowing the conductive pillars 200′ and the new second surface 23b′ of the encapsulant 23′ are at the same height. Therefore, how the conductive pillars or the inactive surface of the chip expose the encapsulant may be adjusted on demands.

In the present invention, the chip 22 is mounted on the carrier 20, then the encapsulant 23 covers the chip 22, and then the carrier 20 is removed, without using the glue film of the prior art. Therefore, the problems of the prior art that the encapsulant excessive glue and chip contamination are solved.

Moreover, in the present invention the chip 22 is mounted on the carrier 20 with the active surface 22a facing the carrier 20. Therefore, the extension/contraction problem due to the heating on the glue film does not happen, and the chip 22 will not be offset. Besides, the chip 22 does not generate any displacement, because the carrier 20, when heated, will not be softened during a package molding process. Accordingly, during the RDL process the circuit layer 25 may be in well contact with the electrode pads 220 of the chip 22, and the yield is thus increased.

In the present invention, the conductive pillars 200 are formed on the carrier 20, such that the supporting force is increased and the whole structure does not suffer the warpage. Therefore, the problem of the prior art that the glue film is used as the only supporting force and thus the warpage is likely to happen is solved. Accordingly, the chip 22 does not offset. Therefore, during the RDL process the circuit layer 25 may be well in contact with the electrode pads 220, and the yield is increased.

The present invention further provides a chip scale package, including: an encapsulant 23 having a first surface 23a and a second surface 23b opposing the first surface 23a; conductive pillars 200 formed in the encapsulant 23 and exposed from the first and second surfaces 23a and 23b of the encapsulant 23, a chip 22 disposed in the encapsulant 23 and exposed from the first surface 23a of the encapsulant 23, a dielectric layer 24 deposited on the first surface 23a of the encapsulant 23, the conductive pillars 200 and the chip 22, a circuit layer 25 deposited on the dielectric layer 24, conductive blind vias 250 formed in the dielectric layer 24, and a solder mask layer 26 formed on the dielectric layer 24 and the circuit layer 25.

In an embodiment of the present invention, the conductive pillars 200 are made of copper, and second holes 230 are formed on the second surface 23b of the encapsulant 23, allowing the conductive pillars 200 to be exposed from the second surface 23b of the encapsulant 23. Alternatively, the conductive pillars 200′ and the second surface 23b′ of the encapsulant 23′ are at the same height, allowing the conductive pillars 200′ to be exposed from the second surface 23b′ of the encapsulant 23′.

The chip 22 has an active surface 22a and an inactive surface 22b opposing the active surface 22a. Electrode pads 220 are formed on the active surface 22a. The active surface 22a is combined with the dielectric layer 24. The inactive surface 22b of the chip 22 may be exposed from the second surface 23b′ of the encapsulant 23′ on demands.

The circuit layer 25 is electrically connected via the conductive blind vias 250 to the electrode pads 220 and the conductive pillar 200.

The solder mask layer 26 has a plurality of first holes 260, allowing a part of the circuit layer 25 to be exposed from the first holes 260. Therefore, a conductive element 27 such as solder balls may be formed on the circuit layer 25 in the first holes 260.

In an embodiment, a metal layer 20a is formed on the conductive pillar 200, and is exposed from the second surface 23b of the encapsulant 23.

The package further comprises a conductive element 28 that is formed on the exposed conductive pillars 200, 200′ or the exposed metal layer 20a.

The package further comprises a built-up structure 25′ that is formed on the dielectric layer 24 and the circuit layer 25. The solder mask layer 26 is formed on an outermost layer of the built-up structure 25′.

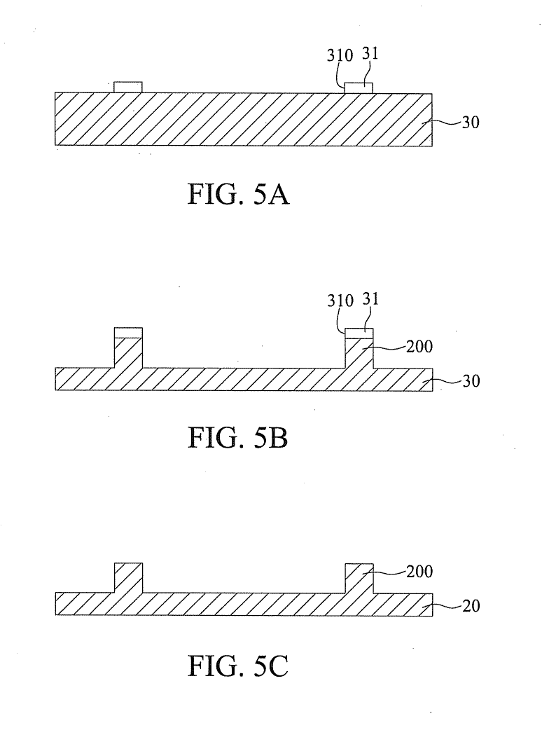

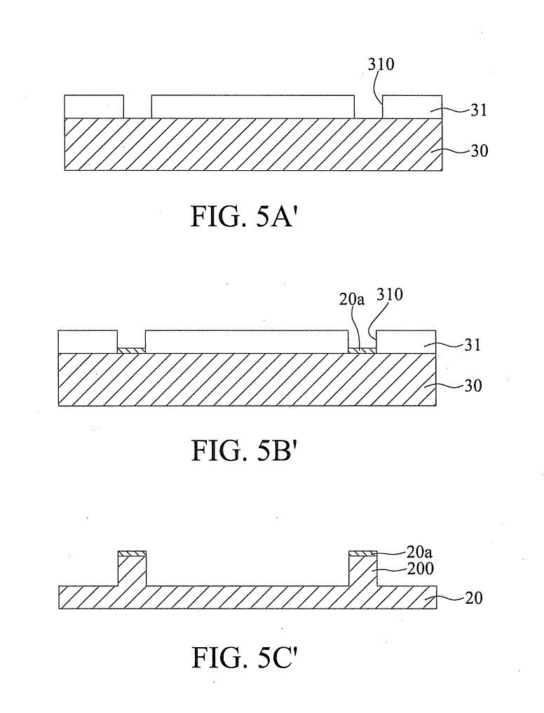

Please refer to FIGS. 5A-5C, which illustrate a method of fabricating the carrier 20 shown in FIG. 4A.

As shown in FIG. 5A, a substrate 30 is provided, and a resistive layer 31 is then formed on the substrate 30. The resistive layer 31 has a plurality of openings 310 that expose a part of the substrate 30.

As shown in FIG. 5B, a part of the substrate 30 in the openings 310 is etched and removed, allowing the conductive pillars 200 to be formed under the resistive layer 31.

As shown in FIG. 5C, the resistive layer 31 is removed, allowing the residual substrate 30 to act as the carrier 20.

Please refer to FIGS. 5A′-5C′, which illustrate a method of fabricating the carrier 20 shown in FIG. 4A′.

As shown in FIG. 5A′, a substrate 30 is provided, and a resistive layer 31 is then formed on the substrate 30. The resistive layer 31 has a plurality of openings 310 that expose a part of the substrate 30.

As shown in FIG. 5B′, a metal layer 20a is formed on the substrate 30 in the openings 310.

As shown in FIG. 5C′, the resistive layer 31 and the part of the substrate 30 under the resistive layer 31 are removed, allowing the conductive pillars 200 to be formed under the metal layer 20a, and the residual substrate 30 to act as the carrier 20.

In sum, the chip scale package and a method of fabricating the chip scale package of the present invention use the design of conductive pillars. Therefore, when a stack process is performed, solder balls may be used to connect another electronic devices directly, such that the process is simplified, and the fabrication time and cost are reduced. Moreover, the present invention uses a carrier to replace the glue film of the prior art, which solves the problems of encapsulant excessive glue and chip contamination.

Besides, through the carrier on which a chip may be mounted and the conductive pillars that may increase the whole supporting force, the warpage does not happen, and the chip does not suffer offset. Accordingly, during the RDL process the circuit layer is well in contact with the electrode pads, and the yield is thus increased. Also, no metal or glue will be residual on the encapsulant when the carrier is removed.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A chip scale package, comprising:
an encapsulant having a first surface and a second surface opposing the first surface;
conductive pillars formed in the encapsulant and exposed from the first surface and the second surface of the encapsulant;
a chip embedded in the encapsulant and having an active surface exposed from the first surface of the encapsulant, an inactive surface opposing the active surface, and a plurality of electrode pads formed on the active surface;
a dielectric layer formed on the first surface of the encapsulant, the exposed conductive pillars, and the active surface of the chip;
a circuit layer formed on the dielectric layer;
conductive blind vias formed in the dielectric layer and electrically connecting the circuit layer to the electrode pads and the conductive pillars; and
a solder mask layer formed on the dielectric layer and the circuit layer and having a plurality of first holes that expose a part of the circuit layer.

2. The chip scale package of claim 1, wherein the conductive pillars are made of copper.

3. The chip scale package of claim 1, further comprising a metal layer formed on the exposed conductive pillars and exposed from the second surface of the encapsulant.

4. The chip scale package of claim 3, further comprising a conductive element formed on the exposed metal layer.

5. The chip scale package of claim 1, wherein the inactive surface of the chip is exposed from the second surface of the encapsulant.

6. The chip scale package of claim 1, wherein the conductive pillars and the second surface of the encapsulant are at a same height.

7. The chip scale package of claim 6, further comprising a conductive element formed on the exposed conductive pillars.

8. The chip scale package of claim 1, further comprising a plurality of second holes formed on the second surface of the encapsulant for exposing the conductive pillars.

9. The chip scale package of claim 1, further comprising a conductive element formed on the circuit layer in the first holes.

10. The chip scale package of claim 1, further comprising a built-up structure formed on the dielectric layer and the circuit layer, wherein the solder mask layer is formed on an outermost layer of the built-up structure.

11. A method of fabricating a chip scale package, comprising:
forming a plurality of neighboring conductive pillars on a carrier, and defining a chip-mounted region on the carrier;
mounting within the chip-mounted region a chip having an active surface and an inactive surface opposing the active surface, with the active surface facing the carrier, wherein a plurality of the electrode pads are formed on the active surface;
forming on the carrier, the conductive pillars and the chip an encapsulant to encapsulate the chip, the encapsulant having a first surface attached to the carrier and an exposed second surface;
removing the carrier to expose the first surface of the encapsulant, the conductive pillars and the active surface of the chip;
forming a dielectric layer on the first surface of the encapsulant, the conductive pillars, and the active surface of the chip;
forming a circuit layer on the dielectric layer, and forming conductive blind vias in the dielectric layer, allowing the circuit layer to be electrically connected via the conductive blind vias to the electrode pads and the conductive pillars;
forming on the dielectric layer and the circuit layer a solder mask layer that has a plurality of first holes for exposing a part of the circuit layer; and
exposing the conductive pillars from the second surface of the encapsulant.

12. The method of claim 11, wherein the carrier is made of copper.

13. The method of claim 11, wherein the carrier is fabricated by:
providing a substrate;
forming on the substrate a resistive layer that has a plurality of openings for exposing a part of the substrate;
removing the part of the substrate in the openings, allowing the conductive pillars to be formed under the resistive layer; and
removing the resistive layer, allowing the remaining substrate to act as the carrier.

14. The method of claim 11, further comprising forming a metal layer on the conductive pillars, allowing the metal layer to expose the second surface of the encapsulant.

15. The method of claim 14, wherein the carrier is fabricated by:
providing a substrate;
forming on the substrate a resistive layer that has a plurality of openings for exposing a part of the substrate;
forming the metal layer on the substrate in the openings; and
removing the resistive layer and a part of the substrate under the resistive layer, so as for the conductive pillars to be formed under the metal layer, and the remaining substrate to act as the carrier.

16. The method of claim 11, wherein the inactive surface of the chip is exposed from the encapsulant.

17. The method of claim 11, further comprising coating the active surface of the chip with an adhesive layer, to allow the chip to be positioned within the chip-mounted region of the carrier, and removing the adhesive layer after the carrier is removed.

18. The method of claim 11, further comprising removing the encapsulant on the conductive pillars, allowing the conductive pillars to be at a same height as the second surface of the encapsulant.

19. The method of claim 11, further comprising forming on the second surface of the encapsulant a plurality of second holes for exposing the conductive pillars.

20. The method of claim 11, further comprising forming a built-up structure on the dielectric layer and the circuit layer, wherein the solder mask layer is formed on an outermost layer of the built-up structure.
